(19) United States
(12) Patent Application Publication
(10) Pub. No.: US 2026/0011614 A1
(43) Pub. Date: Jan. 8, 2026

(54) LAMINATE AND PACKAGE

(71) Applicant: FUJIFILM CORPORATION, Tokyo (JP)

(72) Inventor: Toshihiro Usa, Shizuoka (JP)

(21) Appl. No.: 19/328,620

(22) Filed: Sep. 15, 2025

Related U.S. Application Data
(63) Continuation of application No. PCT/JP2024/035939, filed on Oct. 8, 2024.

(30) Foreign Application Priority Data
Mar. 27, 2024 (JP) 2024-050926

(51) Int. Cl. H01L 23/14; B32B 3/16; B32B 27/30; B65D 81/30; B65H 39/16; B65H 75/14

(52) U.S. Cl. CPC H01L 23/145; B32B 3/16; B32B 27/304; B65D 81/30; B65H 39/16; B65H 75/14; B32B 2307/202; B32B 2307/206; B32B 2307/724; B32B 2439/00; B65H 2301/414

(57) ABSTRACT

Provided are a laminate and a package, which are capable of transporting and storing a mechanically weak anisotropically conductive member which is easily damaged. The laminate includes an anisotropically conductive member including an insulating base material that has electrical insulating properties and a plurality of conduction paths that penetrate in a thickness direction of the insulating base material and have a protruding portion which protrudes from at least one surface of the insulating base material, and an organic film disposed on at least one surface of two surfaces of the anisotropically conductive member facing each other in the thickness direction of the insulating base material. The organic film has a gas permeability of 2.3×10⁸ to 4.6×10⁹ ml/(m²·day·MPa).

### CROSS-REFERENCE TO RELATED APPLICATIONS

This application is a Continuation of PCT International Application No. PCT/JP2024/035939 filed on Oct. 8, 2024, which claims priority under 35 U.S.C. § 119(a) to Japanese Patent Application No. 2024-050926 filed on Mar. 27, 2024. The above applications are hereby expressly incorporated by reference, in their entirety, into the present application.

### BACKGROUND OF THE INVENTION

### 1. Field of the Invention

The present invention relates to a laminate in which an anisotropically conductive member and an organic film are laminated, and a package in which the laminate is housed, and particularly relates to a laminate and a package, in which the anisotropically conductive member has a conduction path which is provided to penetrate a thickness direction of an insulating base material, and the organic film has gas permeability.

### 2. Description of the Related Art

There is an anisotropically conductive member having a conduction path in which a plurality of through-holes provided in an insulating base material are filled with a conductive substance such as metal.

In a case where the anisotropically conductive member is inserted between an electronic component such as a semiconductor element and a circuit board and is simply pressurized, an electrical connection between the electronic component and the circuit board can be obtained, so that the anisotropically conductive bonding member has been widely used as an electrical connecting member of the electronic component or the like such as a semiconductor element or used as a testing connector thereof for carrying out a functional test.

In particular, an electronic component such as a semiconductor element is significantly downsized. In a method of directly connecting a wiring board such as a wire bonding in the related art, flip chip bonding, thermocompression bonding, and the like, stability of electrical connection of the electronic component may not be sufficiently guaranteed, and thus, an anisotropically conductive member has been attracting attention as an electronic connection member.

In a case where the anisotropically conductive member is used as the electronic connection member, the anisotropically conductive member is disposed on a printed circuit board using a surface mounting machine such as a chip mounter. In this case, the anisotropically conductive member is transported and stored using a carrier tape or the like.

For example, JP2005-178073A discloses a package including a carrier tape which has an electronic component housing portion and a cover tape which seals the electronic component housing portion. The cover tape has a base material layer to which antistatic properties are imparted on a surface, an adhesive layer, and an electrostatic induction prevention layer provided between the base material layer and the adhesive layer.

### SUMMARY OF THE INVENTION

JP2005-178073A discloses that the package is obtained by continuously sealing both edge portions of the cover tape in a longitudinal direction with a width of 0.3 to 1.0 mm, and winding the cover tape around a reel. It is disclosed that the electronic component or the like is stored or transported in the form of the package. In addition, in JP2005-178073A, the cover tape is peeled off, and the electronic component or the like is taken out while confirming the presence, orientation, and position of the electronic component or the like by a pickup device.

Here, the above-described anisotropically conductive member has a configuration in which an insulating base material having electrical insulating properties is provided. It is known that the insulating base material is generally mechanically weaker than a metal material; and there is a possibility that the anisotropically conductive member is damaged in a case of being transferred to a print board or the like or during the storage of in a case of being vibrated by an external force.

However, JP2005-178073A does not consider handling of a mechanically weak material which is easily damaged by the vibration or the like.

An object of the present invention is to provide a laminate and a package, which are capable of transporting and storing a mechanically weak anisotropically conductive member which is easily damaged.

In order to achieve the above-described object, an invention [1] is a laminate including an anisotropically conductive member including an insulating base material that has electrical insulating properties and a plurality of conduction paths that penetrate in a thickness direction of the insulating base material and have a protruding portion which protrudes from at least one surface of the insulating base material, and an organic film disposed on at least one surface of two surfaces of the anisotropically conductive member facing each other in the thickness direction of the insulating base material, in which the organic film has a gas permeability of 2.3×10⁸ to 4.6×10⁹ ml/(m²·day·MPa).

An invention [2] is the laminate according to the invention [1], in which the organic film is disposed on the two surfaces facing each other in the thickness direction of the insulating base material.

An invention [3] is the laminate according to the invention [1] or [2], further including a spacer disposed on a surface of the organic film in contact with the anisotropically conductive member.

An invention [4] is the laminate according to any one of the inventions [1] to [3], further including a winding core, in which the laminate is wound around the winding core in a state in which the anisotropically conductive member and the organic film are laminated.

An invention [5] is the laminate according to the invention [4], in which the winding core is composed of a cylinder, and flanges having a diameter larger than a diameter of the winding core are provided at both end parts of the winding core in an axial direction.

An invention [6] is the laminate according to any one of the inventions [1] to [5], in which the organic film is a porous film.

An invention [7] is the laminate according to any one of the inventions [1] to [6], in which a plurality of the anisotropically conductive members are arranged on at least one surface of the organic film in one direction.

An invention [8] is the laminate according to any one of the inventions [1] to [7], in which the anisotropically conductive member is disposed on each of two surfaces facing each other in a thickness direction of the organic film.

An invention [9] is a package including the laminate according to any one of the inventions [1] to [8], and a housing bag which houses the laminate, in which the housing bag has a gas permeability of 1×10⁵ to 1 ml/(m²·day·MPa).

An invention [10] is the package according to the invention [9], in which, in the housing bag, a light transmittance is 1% or less in a wavelength range of 100 to 780 nm.

According to the present invention, it is possible to provide a laminate and a package, which are capable of transporting and storing a mechanically weak anisotropically conductive member which is easily damaged.

### BRIEF DESCRIPTION OF THE DRAWINGS

FIG. 1 is a schematic cross-sectional view showing a first example of the laminate according to the embodiment of the present invention.

FIG. 2 is a schematic cross-sectional view showing an example of a laminated state of the first example of the laminate according to the embodiment of the present invention.

FIG. 3 is a schematic cross-sectional view showing another example of a laminated state of the first example of the laminate according to the embodiment of the present invention.

FIG. 4 is a schematic cross-sectional view showing a second example of the laminate according to the embodiment of the present invention.

FIG. 5 is a schematic cross-sectional view showing an example of a laminated state of the second example of the laminate according to the embodiment of the present invention.

FIG. 6 is a schematic cross-sectional view showing another example of a laminated state of the second example of the laminate according to the embodiment of the present invention.

FIG. 7 is a schematic plan view showing a third example of the laminate according to the embodiment of the present invention.

FIG. 8 is a schematic cross-sectional view showing the third example of the laminate according to the embodiment of the present invention.

FIG. 9 is a schematic perspective view showing a fourth example of the laminate according to the embodiment of the present invention.

FIG. 10 is a schematic cross-sectional view showing a fifth example of the laminate according to the embodiment of the present invention.

FIG. 11 is a schematic view showing a first example of the package according to the embodiment of the present invention.

FIG. 12 is a schematic perspective view showing a second example of the package according to the embodiment of the present invention.

FIG. 13 is a schematic cross-sectional view showing an example of an anisotropically conductive member of the laminate according to the embodiment of the present invention.

FIG. 14 is a schematic plan view showing the example of the anisotropically conductive member of the laminate according to the embodiment of the present invention.

### DESCRIPTION OF THE PREFERRED EMBODIMENTS

Hereinafter, the laminate and the package according to the embodiment of the present invention will be described in detail based on suitable embodiments shown in the accompanying drawings.

The drawings described below are exemplary for describing the present invention and are simplified for describing the present invention. Therefore, the present invention is not limited to the drawings described below.

In the following, “to” indicating the numerical range includes numerical values described on both sides. For example, in a case where ε is a numerical value ε_{α} a to a numerical value ε₆₂, the range of ε is a range including the numerical value ε_{α} and the numerical value ε_{β}, and in mathematical symbols, ε_{α}≤ε≤ε_{β}.

Unless otherwise specified, “parallel” and “orthogonal” include an error range generally allowed in the relevant technical field.

### First Example of Laminate

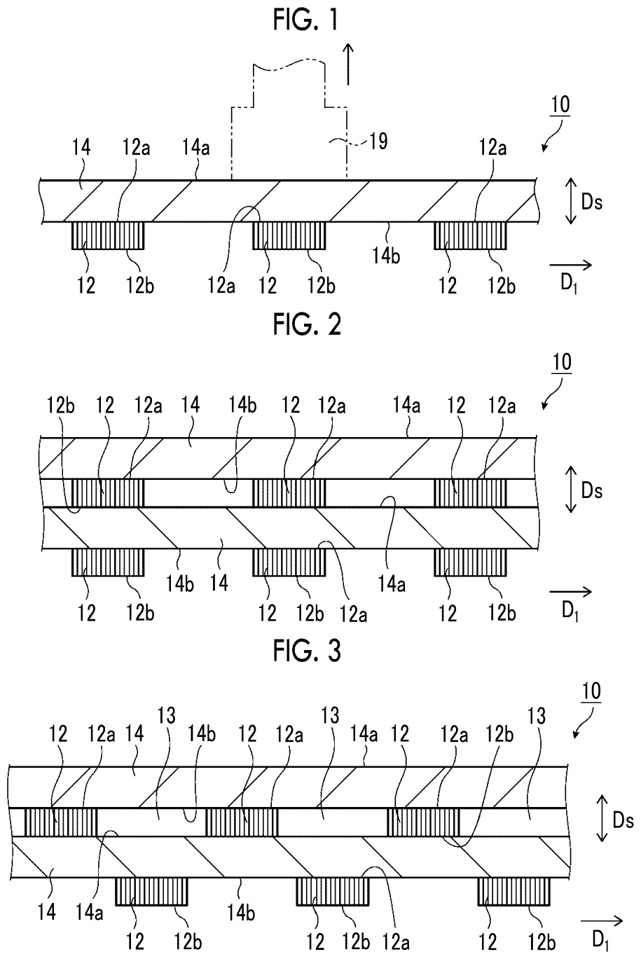

FIG. 1 is a schematic cross-sectional view showing a first example of the laminate according to the embodiment of the present invention. FIG. 2 is a schematic cross-sectional view showing an example of a laminated state of the first example of the laminate according to the embodiment of the present invention. FIG. 3 is a schematic cross-sectional view showing another example of a laminated state of the first example of the laminate according to the embodiment of the present invention.

In FIGS. 1 to 3, a plurality of anisotropically conductive members 12 are shown, but the number of the anisotropically conductive members 12 is not particularly limited to the number shown in FIGS. 1 to 3.

A laminate 10 shown in FIG. 1 has a configuration in which an anisotropically conductive member 12 and an organic film 14 are laminated. A direction in which the anisotropically conductive member 12 and the organic film 14 are laminated is a lamination direction Ds.

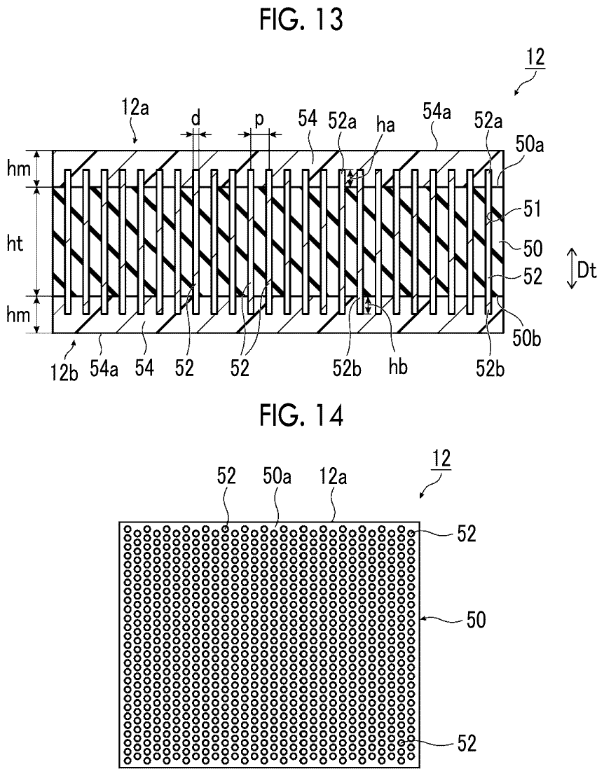

In the laminate 10, the organic film 14 is disposed on at least one surface of two surfaces facing each other in a thickness direction of an insulating base material 50 (see FIG. 13) in the anisotropically conductive member 12. In FIG. 1, the organic film 14 is disposed on a front surface 12a of the anisotropically conductive member 12. A back surface 14b of the organic film 14 is in contact with the front surface 12a of the anisotropically conductive member 12.

The organic film 14 is, for example, an elongated member extending in one direction D₁. A plurality of the anisotropically conductive members 12 are arranged on the back surface 14b of the organic film 14 at intervals along the one direction D₁.

The front surface 12a of the anisotropically conductive member 12 is a front surface 50a (see FIG. 13) of the insulating base material 50 (see FIG. 13). A back surface 12b of the anisotropically conductive member 12 is a back surface 50b (see FIG. 13) of the insulating base material 50 (see FIG. 13). The front surface 12a and the back surface 12b of the anisotropically conductive member 12 are the surfaces facing each other in the thickness direction Dt (see FIG. 13) of the insulating base material 50.

Although the anisotropically conductive member 12 will be described in detail later, the anisotropically conductive member 12 includes an insulating base material 50 (see FIG. 13) that has electrical insulating properties, and a plurality of conduction paths 52 (see FIG. 13) that penetrate in the thickness direction Dt (see FIG. 13) of the insulating base material 50 and have a protruding portion 52a (see FIG. 13) which protrudes from at least one surface of the insulating base material 50. As described above, it is known that the insulating base material is generally mechanically weaker than a metal material.

The organic film 14 has a gas permeability of 2.3×10⁸ to 4.6×10⁹ ml/(m2·day·MPa).

The above-described gas permeability of the organic film 14 can be determined by measuring a flow rate per minute with respect to a unit volume in an environment of a differential pressure of 0.95166 kg/cm² (700 mmHg) and a temperature of 25° C. using a fluid dynamics method.

The fluid dynamics method is a method of obtaining the gas permeability by attaching an organic film to be measured to a gas permeation test device, generating an optional pressure difference, and measuring a rate of gas passing through the organic film or a change in flow.

As the gas permeability of the organic film 14 is 2.3×10⁸ to 4.6×10⁹ ml/(m²·day·MPa), for example, in a case where a head 19 is brought into contact with a front surface 14a of the organic film 14 and the organic film 14 is suctioned using a chip mounter (not shown), the anisotropically conductive member 12 can be suctioned through the organic film 14, and the anisotropically conductive member 12 can be held by the head 19. Therefore, even in a case where the organic film 14 is present between the head 19 and the anisotropically conductive member 12, the anisotropically conductive member 12 can be transported.

By providing the organic film 14 on the front surface 12a of the anisotropically conductive member 12, for example, in a case where the anisotropically conductive member 12 is transported by suctioning the organic film 14 with the head 19 using the chip mounter (not shown), the organic film 14 is present between the head 19 and the anisotropically conductive member 12, so that the organic film 14 serves as a buffer member, and thus damage to the anisotropically conductive member 12, for example, occurrence of chipping and breakage of the insulating base material is suppressed. Furthermore, the plurality of conduction paths 52 (see FIG. 13) having the protruding portion 52a (see FIG. 13) are provided in the anisotropically conductive member 12; but regarding the protruding portion 52a (see FIG. 13), since the organic film 14 is also present between the head 19 and the anisotropically conductive member 12, the damage is suppressed. In this way, the mechanically weak anisotropically conductive member 12 which is easily damaged can be transported.

The damage of the anisotropically conductive member 12 includes, as described above, chipping and breakage of the insulating base material, deformation and cracking of the protruding portion in the conduction path, and the like. For example, in a case where the chipping or the like of the insulating base material occurs, a part of the insulating base material may peel off and cause contamination. In addition, in a case where the anisotropically conductive member is used as the electronic connection member in a state in which the protruding portion is deformed and is in contact with the adjacent protruding portion, there is a possibility that electrical connection may not be appropriately performed. Therefore, it is necessary to suppress the damage to the anisotropically conductive member 12.

In addition, in the laminate 10, since the organic film 14 is provided on the front surface 12a of the anisotropically conductive member 12 as described above, the organic film 14 serves as a buffer member, and thus, even in a case where vibration is applied to the anisotropically conductive member 12 due to an external force during storage, the damage to the anisotropically conductive member 12 is suppressed. As a result, the mechanically weak anisotropically conductive member 12 which is easily damaged can be stably stored with damage suppressed.

In the laminate 10, the back surface 12b of the anisotropically conductive member 12, on which the organic film 14 is not provided, may be configured to have nothing provided thereon. In the configuration, for example, in a case where the laminate 10 is installed on a support (not shown), the back surface 12b of the anisotropically conductive member 12 is in contact with the support.

In addition, the laminate 10 may have a configuration in which the anisotropically conductive members 12 are laminated in the lamination direction Ds as shown in FIG. 2. In FIG. 2, the anisotropically conductive members 12 are laminated so as to overlap each other in the lamination direction Ds. In this case, the anisotropically conductive member 12 is disposed on each of two surfaces facing each other in the thickness direction of the organic film 14.

In a case of laminating the laminate 10, the laminate 10 is not limited to the configuration in which the anisotropically conductive members 12 are laminated to be superimposed in the lamination direction Ds. For example, as shown in FIG. 3, the anisotropically conductive member 12 on the lower side in the lamination direction Ds may be disposed in a region 13 between the anisotropically conductive member 12 on the upper side in the lamination direction Ds in the one direction Di so that the anisotropically conductive member 12 does not overlap in the lamination direction Ds. As shown in FIG. 3, since the anisotropically conductive members 12 do not overlap each other, a force acting on the anisotropically conductive members 12 in the lamination direction Ds can be reduced as compared with a case where the anisotropically conductive members 12 are laminated in the lamination direction Ds, and thus the damage to the insulating base material and the protruding portion of the anisotropically conductive members 12 can be further suppressed. A specific configuration of laminating the laminate 10 will be described later.

### Second Example of Laminate

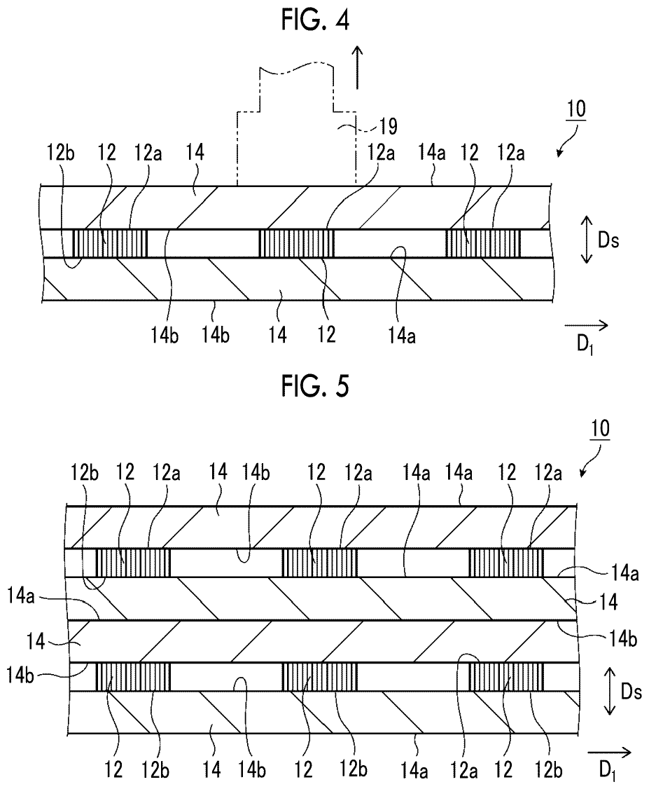

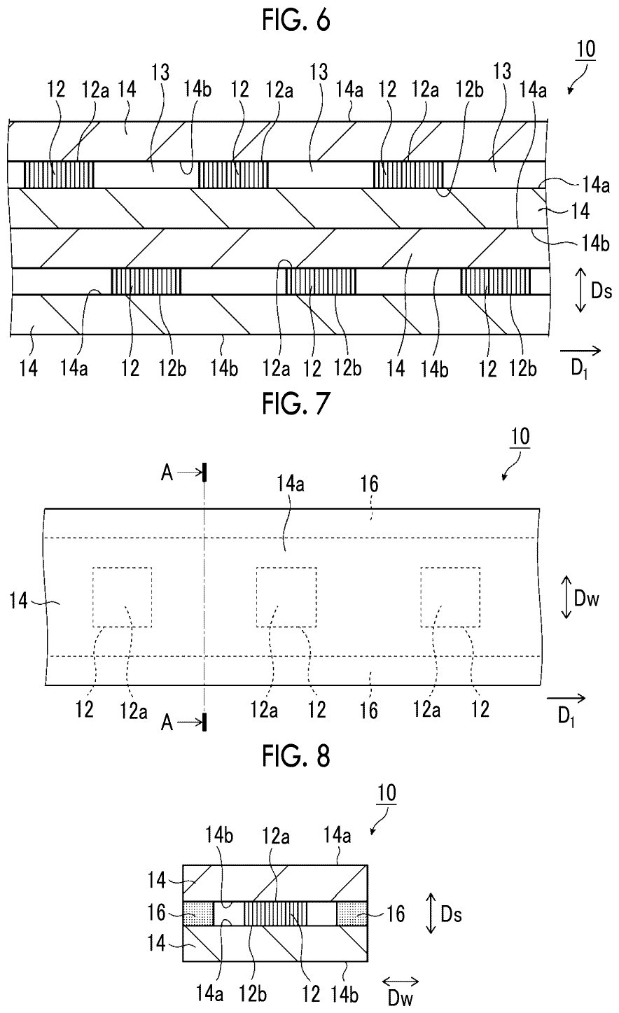

FIG. 4 is a schematic cross-sectional view showing a second example of the laminate according to the embodiment of the present invention. FIG. 5 is a schematic cross-sectional view showing an example of a laminated state of the second example of the laminate according to the embodiment of the present invention. FIG. 6 is a schematic cross-sectional view showing another example of a laminated state of the second example of the laminate according to the embodiment of the present invention.

In FIGS. 4 to 6, a plurality of anisotropically conductive members 12 are shown, but the number of the anisotropically conductive members 12 is not particularly limited to the number shown in FIGS. 4 to 6.

In FIGS. 4 to 6, the same components as those of the laminate 10 shown in FIGS. 1 to 3 are designated by the same reference numerals, and detailed description thereof will not be repeated.

A laminate 10 shown in FIG. 4 is different from the laminate 10 shown in FIG. 1 in that the organic film 14 is disposed on two surfaces of the anisotropically conductive member 12 facing each other in the thickness direction of the insulating base material; and has the same configuration as the laminate 10 shown in FIG. 1 in other configurations.

In the laminate 10 shown in FIG. 4, the organic film 14 is provided on each of the front surface 12a and the back surface 12b of the anisotropically conductive member 12. With the configuration, the two surfaces of the anisotropically conductive member 12 are protected, and thus the damage to the anisotropically conductive member 12 is further suppressed. Therefore, the mechanically weak anisotropically conductive member 12 which is easily damaged can be stably transported and stored with damage suppressed.

In addition, in a case where the anisotropically conductive member 12 is transported using a chip mounter (not shown) as described above, since it is sufficient that the organic film 14 disposed on any one of the front surface 12a side or the back surface 12b side of the anisotropically conductive member 12 is suctioned by the head 19, the degree of freedom of transportation of the anisotropically conductive member 12 is also high.

In addition, for example, in a case where the laminate 10 is unwound from a state of being wound, since the organic film 14 is provided on the front surface 12a side and the back surface 12b side of the anisotropically conductive member 12, the degree of freedom of unwinding is also high.

In addition, the laminate 10 may have a configuration in which the anisotropically conductive members 12 are laminated in the lamination direction Ds as shown in FIG. 5. In FIG. 5, the anisotropically conductive members 12 are laminated by overlapping each other in the lamination direction Ds. In a case of laminating the laminate 10, the laminate 10 is not limited to the configuration in which the anisotropically conductive members 12 are laminated to be superimposed in the lamination direction Ds. For example, as shown in FIG. 6, the anisotropically conductive member 12 on the lower side in the lamination direction Ds may be disposed in a region 13 between the anisotropically conductive member 12 on the upper side in the lamination direction Ds in the one direction D₁ so that the anisotropically conductive member 12 does not overlap in the lamination direction Ds. As shown in FIG. 6, since the anisotropically conductive members 12 do not overlap each other, a force acting on the anisotropically conductive members 12 in the lamination direction Ds can be reduced as compared with a case where the anisotropically conductive members 12 are laminated in the lamination direction Ds, and thus the damage to the insulating base material and the protruding portion of the anisotropically conductive members 12 can be further suppressed. A specific configuration of laminating the laminate 10 will be described later.

The laminate 10 shown in FIG. 4 has the configuration in which the organic film 14 is provided on the front surface 12a side and the back surface 12b side of the anisotropically conductive member 12, but the present invention is not limited thereto. Any one of the organic film 14 on the front surface 12a side and the back surface 12b side of the anisotropically conductive member 12 may not be the organic film 14. For example, a tape formed of polystyrene (PS), polyethylene terephthalate (PET), or polypropylene (PP), other than the organic film 14, may be disposed instead of the organic film 14.

As the tape instead of the organic film 14, a carrier tape used in a mounting device for an electronic component can be used. In addition, an embossed carrier tape in which a plurality of recess portions for housing the anisotropically conductive member 12 are arranged along one direction extending from the tape can also be used instead of the organic film 14. In the embossed carrier tape, since one anisotropically conductive member is disposed in one recess portion, the anisotropically conductive member 12 can be more stably housed. In a case where the embossed carrier tape is used, the anisotropically conductive member 12 may be placed on the recess portion and then covered with the organic film 14 to be sealed.

### Third Example of Laminate

FIG. 7 is a schematic plan view showing a third example of the laminate according to the embodiment of the present invention. FIG. 8 is a schematic cross-sectional view showing the third example of the laminate according to the embodiment of the present invention. FIG. 8 shows a cross section taken along a line A-A of FIG. 7.

In FIG. 7, a plurality of anisotropically conductive members 12 are shown, but the number of the anisotropically conductive members 12 is not particularly limited to the number shown in FIG. 7.

In FIGS. 7 and 8, the same components as those of the laminate 10 shown in FIGS. 4 to 6 are designated by the same reference numerals, and detailed description thereof will not be repeated.

A laminate 10 shown in FIGS. 7 and 8 is different from the laminate 10 shown in FIG. 4 in that a spacer 16 is provided on a surface of the organic film 14 in contact with the anisotropically conductive member 12; and has the same configuration as the laminate 10 shown in FIG. 4 in other configurations.

In the laminate 10, as shown in FIGS. 7 and 8, the spacer 16 is disposed on both sides of the organic film 14 in a width direction Dw orthogonal to the one direction D₁ of the organic film 14 on the front surface 14a of the organic film 14 on the lower side in the lamination direction Ds. The spacer 16 regulates movement of the anisotropically conductive member 12 in the width direction Dw, and reduces the force acting on the anisotropically conductive member 12 in the lamination direction Ds. Therefore, the damage to the anisotropically conductive member 12 can be further suppressed.

The spacer 16 is formed of, for example, a tape formed of polytetrafluoroethylene (PTFE), polystyrene (PS), polyethylene terephthalate (PET), or polypropylene (PP).

In addition, it is preferable that a thickness of the spacer 16 in the lamination direction Ds is the same as a thickness of the anisotropically conductive member 12 in the lamination direction Ds. As a result, the movement of the anisotropically conductive member 12 in the lamination direction Ds is restricted, and even in a case where vibration is applied to the anisotropically conductive member 12 due to an external force during transportation, transport, or storage, the damage is further suppressed.

### Fourth Example of Laminate

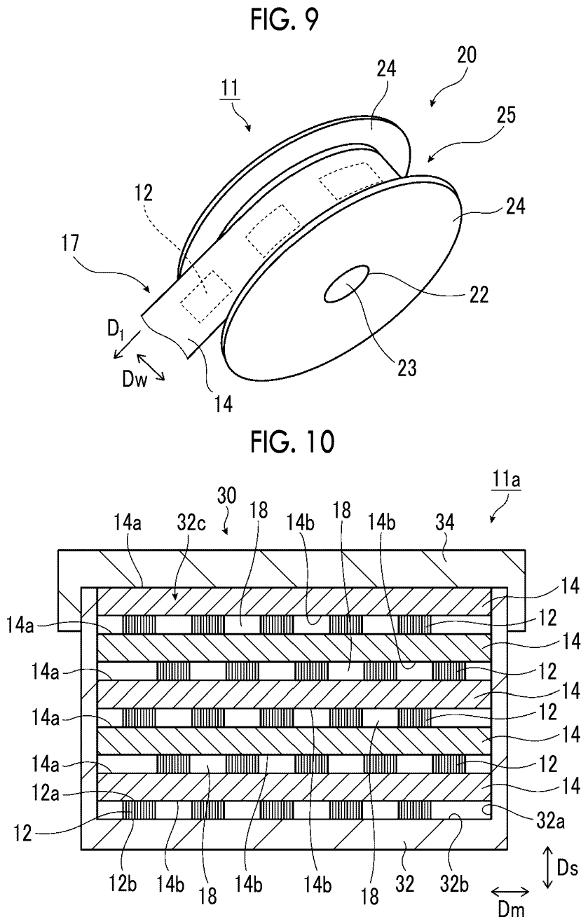

FIG. 9 is a schematic perspective view showing a fourth example of the laminate according to the embodiment of the present invention.

In FIG. 9, the same components as those of the laminate 10 shown in FIG. 1 are designated by the same reference numerals, and detailed description thereof will not be repeated.

A laminate 11 shown in FIG. 9 is different from the laminate 10 shown in FIG. 1 in that the laminate 11 further includes a winding core 22 and is wound around the winding core 22 in a state in which the anisotropically conductive member 12 and the organic film 14 are laminated; and has the same configuration as the laminate 10 shown in FIG. 1 in other configurations.

In the laminate 11 shown in FIG. 9, a state in which the anisotropically conductive member 12 and the organic film 14 are laminated is referred to as a laminated material 17. The laminated material 17 is wound around the winding core 22 of a reel 20.

In the reel 20, for example, the winding core 22 is composed of a cylinder, and flanges 24 having a diameter larger than a diameter of the winding core 22 are provided at both end parts of the winding core 22 in an axial direction. The winding core 22 has a through-hole 23. A rotary shaft (not shown) for rotating the reel 20 is inserted into the through-hole 23.

The flange 24 is composed of, for example, a flat plate, and has a circular outer shape. The diameter of the flange 24 is larger than the diameter of the winding core 22 as described above. In a case where the outer shape of the flange 24 is circular, the diameter of the flange 24 is a diameter thereof. In a case where the outer shape of the winding core 22 is circular, the diameter of the winding core 22 is a diameter thereof.

The laminated material 17 has one end part in the one direction D₁, which is connected to the winding core 22, and is wound around the winding core 22 between the flanges 24.

The reel 20 is made of a material which is not particularly limited, and is made of, for example, various plastics.

In addition, the winding core 22 is not particularly limited to the cylinder and can have a known winding core shape. The size of the diameter and the length of the winding core 22 in the axial direction are also not particularly limited, and are appropriately determined depending on the application and the like.

In a case where a curvature of the laminated material 17 wound around the winding core 22 is denoted by X(1/m) and a curvature radius is denoted by R(m), it is preferable that 5≤X(1/m)≤40, that is, 0.025≤R(m)≤0.2. In a case where the laminated material 17 is wound around the winding core 22, it is preferable that the diameter in a case where the winding core 22 is a cylinder or the equivalent circle diameter in a case where the winding core 22 is not a cylinder is set such that the curvature X (1/m) and the curvature radius R(m) of the laminated material 17 are set to 5≤X(1/m)≤40, that is, 0.025≤R(m)≤0.2 as described above.

The reel 20 is configured to have the flange 24; but the present invention is not limited thereto, and for example, the reel 20 may be configured to not have the flange 24. However, since the flange 24 regulates the position of the organic film 14 in the width direction Dw and the anisotropically conductive member 12 can prevent the organic film 14 from falling, it is preferable that the reel 20 has the flange 24.

As shown in FIG. 4, the laminated material 17 may have a configuration in which the organic film 14 is disposed on both surfaces of the anisotropically conductive member 12. In a case where the laminated material 17 is wound around the winding core 22, for example, the anisotropically conductive member 12 is in the laminated state as shown in FIGS. 2, 3, 5, and 6.

### Fifth Example of Laminate

FIG. 10 is a schematic cross-sectional view showing a fifth example of the laminate according to the embodiment of the present invention.

In FIG. 10, the same components as those of the laminate 10 shown in FIG. 1 are designated by the same reference numerals, and detailed description thereof will not be repeated.

A laminate 11a shown in FIG. 10 is different from the laminate 10 shown in FIG. 1 in that the laminate 11a includes a housing container 30, the anisotropically conductive member 12, and the organic film 14, and the anisotropically conductive member 12 and the organic film 14 are laminated in the housing container 30; and has the same configuration as the laminate 10 shown in FIG. 1 in other configurations.

The housing container 30 includes a container main body 32 and a lid 34. The container main body 32 is composed of, for example, a tubular member having a bottom portion 32b. The upper side of the bottom portion 32b of the container main body 32 is open, and an opening portion 32c is provided. The lid 34 is a member which closes the opening portion 32c of the container main body 32. The container main body 32 and the lid 34 are, for example, cylindrical members, and an outer shape of the opening portion 32c of the container main body 32 is circular. For example, a silicon wafer case can be used as the housing container 30.

The anisotropically conductive member 12 and the organic film 14 are disposed such that the anisotropically conductive member 12 and the organic film 14 are repeatedly laminated in order from a bottom portion 34b side in an inside portion 32a of the container main body 32.

In the laminate 11a, for example, the anisotropically conductive member 12 on the lower side in the lamination direction Ds is disposed in a space 18 in a lateral direction Dm orthogonal to the lamination direction Ds of the anisotropically conductive member 12 on the upper side in the lamination direction Ds so that the anisotropically conductive members 12 do not overlap each other in the lamination direction Ds. As a result, a force acting on the anisotropically conductive member 12 in the lamination direction Ds can be reduced, and thus the damage to the insulating base material and the protruding portion of the anisotropically conductive member 12 can be further suppressed.

In FIG. 10, five layers of the anisotropically conductive member 12 and five layers of the organic film 14 are disposed; but the number of layers to be disposed is appropriately determined according to the size of the housing container 30 or the size of the anisotropically conductive member 12, and is not particularly limited to the configuration shown in FIG. 10.

As shown in FIG. 10, by laminating and housing the anisotropically conductive members 12 in the housing container 30, a large number of the anisotropically conductive members 12 can be stably stored with damage suppressed, and can also be transported as the housing container 30. Even in a case where the housing container 30 is transported, the damage to the anisotropically conductive member 12 is suppressed.

The anisotropically conductive members 12 are laminated so as not to overlap each other in the lamination direction Ds; but the present invention is not limited thereto, and the anisotropically conductive members 12 may be laminated by being superimposed in the lamination direction Ds as shown in FIG. 2.

In addition, the organic film 14 may be disposed on the front surface 12a and the back surface 12b of the anisotropically conductive member 12, respectively; and the anisotropically conductive member 12 and the organic film 14 may be repeatedly laminated in the order of the anisotropically conductive member 12 and the organic film 14 in the container main body 32.

In addition, the above-described spacer 16 (see FIG. 8) may be provided in the space 18 between the adjacent anisotropically conductive members 12 in the lateral direction Dm orthogonal to the lamination direction Ds. The spacer 16 regulates movement of the anisotropically conductive member 12 in the lateral direction Dm, and reduces the force acting on the anisotropically conductive member 12 in the lamination direction Ds. Therefore, the damage to the anisotropically conductive member 12 can be further suppressed.

Even in the laminate 11a, it is preferable that a thickness of the spacer 16 in the lamination direction Ds is the same as a thickness of the anisotropically conductive member 12 in the lamination direction Ds. As a result, the movement of the anisotropically conductive member 12 in the lamination direction Ds is restricted, and even in a case where vibration is applied to the anisotropically conductive member 12 due to an external force during transport or storage, the damage is further suppressed.

### First Example of Package

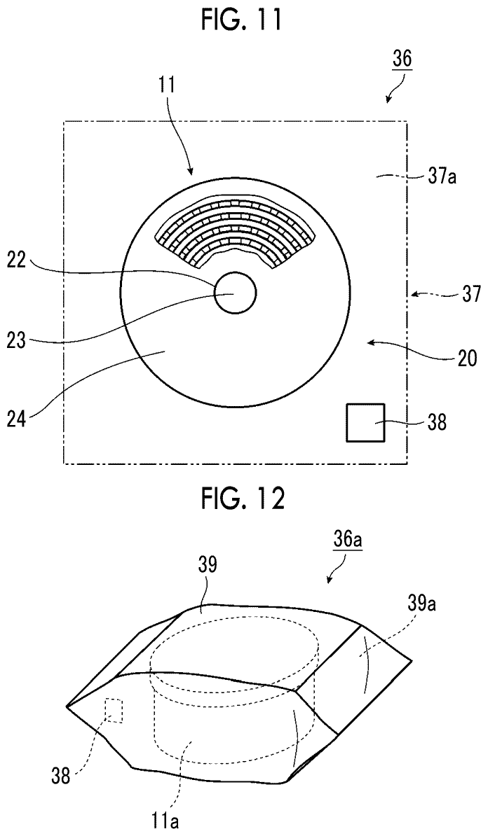

FIG. 11 is a schematic view showing a first example of the package according to the embodiment of the present invention.

In FIG. 11, the same components as those of the laminate 11 shown in FIG. 9 are designated by the same reference numerals, and detailed description thereof will not be repeated.

A package 36 shown in FIG. 11 includes the laminate 11 and a housing bag 37 which houses the laminate 11. The laminate 11 is stored in an inside portion 37a of the housing bag 37.

The housing bag 37 has a gas permeability of 1×10⁵ to 1 ml/(m²·day·MPa).

The gas permeability of the housing bag 37 is measured using, for example, Japanese Industrial Standards (JIS) K 7126-1:2006 of Plastics-Films and Sheets-Gas Permeability Test Method.

In the package 36, entry of oxygen into the inside portion 37a is suppressed by the housing bag 37, and in a case where the conduction path of the anisotropically conductive member 12 is made of metal, oxidation of the conduction path is suppressed. Therefore, in a case of transporting and storing the anisotropically conductive member 12, the anisotropically conductive member 12 can be transported and stored in a state of being wound around the reel 20 while suppressing deterioration of performance such as conductivity.

In addition, the package 36 may be provided with an oxygen scavenger 38 in the inside portion 37a of the housing bag 37, or a desiccant (not shown) may be provided in addition to the oxygen scavenger 38. In addition, the inside portion 37a of the housing bag 37 may be replaced with an inert gas such as argon gas and nitrogen gas, as inert gas replacement packaging, or may be vacuum-packaged.

In addition, in a case where incidence of light into the inside portion 37a of the housing bag 37 is suppressed, the housing bag 37 preferably has light shielding properties. In this case, a light transmittance of the housing bag 37 is preferably 1% or less at a wavelength range of 100 to 780 nm.

The light transmittance of the housing bag 37 is measured in a wavelength range of 100 nm to 780 nm using a spectrophotometer.

### Second Example of Package

FIG. 12 is a schematic perspective view showing a second example of the package according to the embodiment of the present invention.

In FIG. 12, the same components as those of the laminate 11a shown in FIG. 10 and the package 36 shown in FIG. 11 are designated by the same reference numerals, and detailed description thereof will not be repeated.

A package 36a shown in FIG. 12 includes the laminate 11a and a housing bag 39 which houses the laminate 11a. The laminate 11a is housed in an inside portion 39a of the housing bag 39.

In the package 36a, entry of oxygen into the inside portion 39a is suppressed by the housing bag 39, and in a case where the conduction path of the anisotropically conductive member 12 is made of metal, oxidation of the conduction path is suppressed. Therefore, in a case of transporting and storing the anisotropically conductive member 12, the anisotropically conductive member 12 can be transported and stored in a state of being housed in the housing container 30 while suppressing deterioration of performance such as conductivity.

In addition, the package 36a may be provided with an oxygen scavenger 38 in the inside portion 39a of the housing bag 39, or a desiccant (not shown) may be provided in addition to the oxygen scavenger 38. In addition, the inside portion 39a of the housing bag 39 may be replaced with an inert gas such as argon gas and nitrogen gas, as inert gas replacement packaging, or may be vacuum-packaged.

In addition, in a case where incidence of light into the inside portion 39a of the housing bag 39 is suppressed, the housing bag 39 preferably has light shielding properties. In this case, a light transmittance of the housing bag 39 is preferably 1% or less at a wavelength range of 100 to 780 nm.

The light transmittance of the housing bag 39 is measured by the same method as the above-described method of measuring the light transmittance of the housing bag 37.

### Organic Film

As described above, the organic film has a gas permeability of 2.3×10⁸ to 4.6×10⁹ ml/(m²·day·MPa). The organic film is preferably a porous membrane in order to facilitate the suction of the anisotropically conductive member.

In addition, the organic film contains a polymer, and the polymer contains, for example, a fluorine atom. The organic film is formed of, for example, polyethylene terephthalate (PTFE). More specifically, as the organic film, POREFLON (registered trademark) membrane FP series manufactured by SUMITOMO ELECTRIC FINE POLYMER, INC. can be used.

The organic film has, for example, a bending elastic modulus of 100 to 10,000 (MPa) at a temperature of 25° C.

### Housing Bag

As described above, the housing bag has a gas permeability of 1×10⁻⁵ to 1 ml/(m²·day·MPa).

As the housing bag, for example, a gas barrier bag (PTS bag (product name) and aluminum bag (product name)) used in an RP system (registered trademark) manufactured by MITSUBISHI GAS CHEMICAL COMPANY, INC. can be used.

In addition, in a case where incidence of light is suppressed as described above, the housing bag preferably has light shielding properties. In this case, the light transmittance of the housing bag is preferably 1% or less at a wavelength range of 100 to 780 nm. The method of measuring the light transmittance of the housing bag is as described above.

The light transmittance of the housing bag is a light transmittance of a film material forming the housing bag. For example, in a case where the housing bag is produced by sealing a resin film material, a light transmittance of the resin film material is the light transmittance of the housing bag.

### Anisotropically Conductive Member

FIG. 13 is a schematic cross-sectional view showing an example of the anisotropically conductive member of the laminate according to the embodiment of the present invention. FIG. 14 is a schematic plan view showing the example of the anisotropically conductive member of the laminate according to the embodiment of the present invention. FIG. 14 is a plan view of an anodized film of FIG. 13 as viewed from the surface side, and shows a state in which a resin layer 54 is not present.

An anisotropically conductive member 12 shown in FIG. 13 includes an insulating base material 50 having electrical insulating properties, and a plurality of conduction paths 52 that penetrate in a thickness direction Dt of the insulating base material 50, are provided in a state of being electrically insulated from each other, and have a protruding portion which protrudes from at least one surface. In addition, the resin layer 54 which covers at least one surface of the insulating base material 50 is provided. The anisotropically conductive member 12 has conductivity in the thickness direction Dt of the insulating base material 50.

In the above-described laminate 10 (see FIG. 1), the anisotropically conductive member 12 is laminated with the organic film 14 in the thickness direction Dt of the insulating base material 50 and the lamination direction Ds of the laminate 10 being parallel to each other.

In the anisotropically conductive member 12, the resin layer 54 is not necessarily required, and a configuration in which the resin layer 54 is not provided may be adopted.

The plurality of conduction paths 52 are provided on the insulating base material 50 in a state of being electrically insulated from each other. In this case, for example, the insulating base material 50 has a plurality of pores 51 penetrating in the thickness direction Dt. The conduction path 52 is provided in a plurality of pores 51. The conduction path 52 protrudes from a front surface 50a of the insulating base material 50. In addition, the conduction path 52 protrudes from a back surface 50b of the insulating base material 50.

The conduction path 52 may protrude from one surface of the insulating base material 50 in the thickness direction Dt. For example, the resin layer 54 is provided on the surface of the insulating base material 50, from which the conduction path 52 protrudes. The resin layer 54 covers a protruding portion 52a of the conduction path 52, and the protruding portion 52a is embedded in the resin layer 54. In addition, the resin layer 54 covers a protruding portion 52b of the conduction path 52, and the protruding portion 52b is embedded in the resin layer 54.

The insulating base material 50 is composed of, for example, an anodized film. The anodized film is formed by, for example, anodizing a valve metal.

The front surface 50a of the insulating base material 50 and a back surface 50b of the insulating base material 50 are surfaces facing each other in the thickness direction Dt of the insulating base material 50.

The anisotropically conductive member 12 has anisotropic conductivity and has conductivity in the thickness direction Dt as described above, but has low conductivity in a direction parallel to the front surface 50a of the insulating base material 50.

As shown in FIG. 14, the anisotropically conductive member 12 has, for example, a quadrangular outer shape. The outer shape and size of the anisotropically conductive member 12 are appropriately determined according to the application and the like.

For example, the anisotropically conductive member 12 is bonded in a state in which the resin layer 54 is not present or in a state in which nothing is present on a surface 54a even in a case where the resin layer 54 is present.

Hereinafter, the configuration of the anisotropically conductive member will be described in more detail. The anisotropically conductive member has the same configuration as the structure described in WO2022/163260A, and can be manufactured in the same manner as in the above-described structure.

### Insulating Base Material

The insulating base material 50 is composed of a conductor, and is in a state in which a plurality of conduction paths 52 are electrically insulated from each other. As described above, the insulating base material 50 has electrical insulating properties. In addition, the insulating base material 50 has a plurality of pores 51 in which the conduction path 52 is formed. A formulation and the like of the insulating base material 50 will be described later.

A length of the insulating base material 50 in the thickness direction Dt, that is, a thickness ht of the insulating base material 50 is preferably in a range of 1 to 1,000 μm, more preferably in a range of 5 to 500 μm, and still more preferably in a range of 10 to 300 μm. In a case where the thickness ht of the insulating base material 50 is within the range, the handleability of the insulating base material 50 is improved.

From the viewpoint of ease of winding, the thickness ht of the insulating base material 50 is preferably 30 μm or less, and more preferably 5 to 20 μm.

The thickness of the insulating base material can be measured by cutting the insulating base material in the thickness direction Dt using a focused ion beam (FIB), and acquiring a captured image at a magnification of 50,000 times using a field emission scanning electron microscope (FE-SEM) from a cross section thereof. In the captured image, lengths of 10 portions corresponding to the thickness of the insulating base material are measured, and an average value of the lengths of the 10 measured portions is obtained. The average value is defined as the thickness of the insulating base material.

### Average Diameter of Pores

An average diameter of the pores 51 is preferably 1 μm or less, more preferably 5 to 500 nm, still more preferably 20 to 400 nm, even more preferably 40 to 200 nm, and most preferably 50 to 100 nm. In a case where the average diameter d of the pores 51 is 1 μm or less and is within the above-described range, it is possible to obtain the conduction path 52 having the above-described average diameter.

The average diameter of the pores 51 can be measured by imaging the surface of the insulating base material 50 from directly above at a magnification of 100 to 10,000 times with a scanning electron microscope (SEM) to obtain a captured image. At least 20 pores of which a periphery is connected in an annular shape are extracted from the captured image, diameters thereof are measured to obtain opening diameters, and an average value of the opening diameters is calculated as the average diameter of the pores.

For the magnification, a magnification in the above-described range can be appropriately selected so that the captured image from which 20 or more pores can be extracted is obtained. In addition, the opening diameter is measured as the maximum value of the distance between the end parts of the pore portions. That is, since the shape of the opening portion of the pores is not limited to the substantially circular shape, in a case where the shape of the opening portion is non-circular, the maximum value of the distance between the end parts of the pore portions is defined as the opening diameter. Therefore, for example, even in a case of pores having a shape in which two or more pores are integrated, the pores are regarded as one pore, and the maximum value of the distance between the end parts of the pore portions is regarded as the opening diameter.

### Conduction Path

The plurality of conduction paths 52 are provided in the insulating base material 50, for example, in the anodized film as described above in a state of being electrically insulated from each other.

The plurality of conduction paths 52 have conductivity. The conduction path is formed of a conductive substance. The conductive substance is not particularly limited, and examples thereof include a metal. Specific suitable examples of the metal include gold (Au), silver (Ag), copper (Cu), aluminum (Al), magnesium (Mg), nickel (Ni), zinc (Zn), and cobalt (Co). From the viewpoint of electrical conductivity, copper, gold, aluminum, nickel, or cobalt is preferable, copper or gold is more preferable, and copper is most preferable.

Since the metal is more excellent in ductility and the like and is easily deformed than the oxide conductor, and is easily deformed even in compression during bonding, it is preferable that the conduction path is composed of a metal.

A height of the conduction path 52 in the thickness direction Dt is preferably 10 to 300 μm and more preferably 20 to 30 μm.

### Shape of Conduction Path

An average diameter d of the conduction path 52 is preferably 1 μm or less, more preferably 5 to 500 nm, still more preferably 20 to 400 nm, even more preferably 40 to 200 nm, and most preferably 50 to 100 nm.

A density of the conduction paths 52 is preferably 20,000 pieces/mm² or more, more preferably 2,000,000 pieces/mm² or more, still more preferably 10,000,000 pieces/mm² or more, particularly preferably 50,000,000 pieces/mm² or more, and most preferably 100,000,000 pieces/mm² or more.

Furthermore, a center-to-center distance p of adjacent conduction paths 52 is preferably 20 nm to 500 nm, more preferably 40 nm to 200 nm, and still more preferably 50 nm to 140 nm.

The average diameter of the conduction path is obtained by imaging the surface of the insulating base material from directly above at a magnification of 100 to 10,000 times with a scanning electron microscope to obtain a captured image. At least 20 conduction paths of which a periphery is connected in an annular shape are extracted from the captured image, diameters thereof are measured to obtain opening diameters, and an average value of the opening diameters is calculated as the average diameter of the conduction paths.

For the magnification, a magnification in the above-described range can be appropriately selected so that the captured image from which 20 or more conduction paths can be extracted is obtained. In addition, in a case where the shape of the opening portion is a non-circular shape, the maximum value of the distance between the end parts of the conduction path portions is defined as the opening diameter. Therefore, for example, even in a case of conduction paths having a shape in which two or more conduction paths are integrated, the conduction paths are regarded as one pore, and the maximum value of the distance between the end parts of the conduction path portions is regarded as the opening diameter. The average diameter d of the conduction path 52 is the same as the average diameter of the protruding portion.

In the captured image of the insulating base material 50 obtained as described above, a center position (not shown) of a specified conduction path is further specified as the center-to-center distance p between the adjacent conduction paths 52. A distance between center positions of the adjacent conduction paths is obtained at 10 locations. An average value thereof is defined as the center-to-center distance p of adjacent conduction paths 52. The center position is a center position of a region corresponding to the conduction path 52 in the above-described captured image. In the captured image, a known image analysis method is used to calculate the center position of the region.

### Protruding Portion

The protruding portion is a part of the conduction path, and has a columnar shape. It is preferable that the protruding portion has a columnar shape since a contact area with a bonding target can be increased.

An average protrusion length ha of the protruding portions 52a and an average length hb of the protruding portions 52b are preferably 10 nm to 1,000 nm and more preferably 50 nm to 500 nm. In a case where the average protrusion length ha and the average length hb are 10 nm to 1,000 nm, the adhesiveness between the resin layer 54 and the insulating base material 50 is improved.

The average protrusion length ha of the protruding portions 52a and the average length hb of the protruding portions 52b are obtained by acquiring a cross-sectional image of the protruding portion using a scanning electron microscope as described above, measuring the height of the protruding portion at 10 points based on the cross-sectional image, and calculating an average value of the measured values.

Regarding the conduction path 52, an interval with the adjacent protruding portion is preferably 20 nm to 200 nm and more preferably 40 nm to 100 nm. In a case where the interval with the adjacent protruding portion is within the above-described range, the interval of the conduction path 52 can be maintained even on the front surface 50a or the back surface 50b of the insulating base material 50 of the conduction path 52. As a result, in a case of bonding to a connection target such as a semiconductor device, the short-circuit of the conduction path 52 is suppressed, and thus the reliability during bonding is further increased.

### Resin Layer

The resin layer covers at least one surface of the front surface or the back surface of the insulating base material as described above, and protects the insulating base material and the conduction path. In a case where the conduction path has a protruding portion, the protruding portion is embedded in the resin layer. That is, the resin layer covers an end part of the conduction path which protrudes from the insulating base material, and protects the protruding portion.

In order to exhibit the above-described function, it is preferable that the resin layer exhibits fluidity in a temperature range of 50° C. to 200° C. and is cured at 200° C. or higher. The resin layer is, for example, a thermoplastic layer composed of a thermoplastic resin or the like, and the resin layer will be described in detail later.

An average thickness hm of the resin layer 54 is preferably 10 μm or less, more preferably 5 μm or less, and still more preferably 1 μm or less. In a case where the average thickness hm of the resin layer 54 is 10 μm or less as described above, the protruding portion of the conduction path 52 can be protected, and the effect of filling the periphery of the electrode during the bonding to a connection target such as a semiconductor device can be sufficiently exhibited.

The average thickness hm of the resin layer 54 is the average distance from the front surface 50a of the insulating base material 50 or the average distance from the back surface 50b of the insulating base material 50. For the above-described average thickness hm of the resin layer 54, the resin layer is cut in the thickness direction Dt of the anisotropically conductive member 12, and an image of the cut cross section is acquired with a scanning electron microscope. In the captured image, a distance from the front surface 50a of the insulating base material 50 corresponding to the resin layer is measured at 10 points, and an average value of lengths of the 10 measured points is obtained. The average value is defined as the average thickness hm of the resin layer 54 on the front surface 50a side of the insulating base material 50.

Furthermore, a distance from the back surface 50b of the insulating base material 50 is measured at 10 points. An average value of the lengths of the 10 measured points is obtained. The average value is defined as the average thickness hm of the resin layer 54 on the back surface 50b side of the insulating base material 50.

As the resin layer, a formulation shown below can also be used. Hereinafter, the formulation of the resin layer will be described. For example, the resin layer contains a polymer material, and may contain an antioxidant material.

Specific examples of a resin material constituting the resin layer include thermoplastic resins such as an ethylene-based copolymer, a polyamide resin, a polyester resin, a polyurethane resin, a polyolefin-based resin, an acrylic resin, an acrylonitrile-based resin, and a cellulose-based resin. As the resin material constituting the resin layer 54, polyacrylonitrile can also be used.

As the resin layer, in addition to the above, for example, a resin layer containing a main composition containing an acrylic polymer, an acrylic monomer, and a maleimide compound, which is described in WO2022/163260A, can be used.

The present invention is basically configured as described above. The laminate and the package according to the embodiment of the present invention have been described in detail above, but the present invention is not limited to the above-described embodiments, and various improvements and changes can be made without departing from the spirit of the present invention.

### EXPLANATION OF REFERENCES

10, 11, 11a: laminate
12: anisotropically conductive member
12a, 14a, 50a, 54a: front surface
12b, 14b, 50b: back surface
13: region
14: organic film
16: spacer
17: laminated material
18: space
19: head
20: reel
22: winding core
23: through-hole
24: flange
30: housing container
32: container main body
32a, 37a, 39a: inside portion
32b: bottom portion
32c: opening portion
34: lid
34b: bottom portion
36: package
36a: package
37, 39: housing bag
38: oxygen scavenger
50: insulating base material
51: pore
52: conduction path
52a, 52b: protruding portion
54: resin layer
D₁: one direction
Dm: lateral direction
Ds: lamination direction
Dt: thickness direction
Dw: width direction
d: average diameter
hm: average thickness
ht: thickness
p: center-to-center distance

What is claimed is:

1. A laminate comprising:
an anisotropically conductive member including an insulating base material that has electrical insulating properties and a plurality of conduction paths that penetrate in a thickness direction of the insulating base material and have a protruding portion which protrudes from at least one surface of the insulating base material; and
an organic film disposed directly on at least one surface of two surfaces of the anisotropically conductive member facing each other in the thickness direction of the insulating base material,
wherein the organic film has a gas permeability of oxygen of 2.3×10⁸ to 4.6×10⁹ ml/(m²·day·MPa), and contains a polymer containing a fluorine atom.

2. The laminate according to claim 1,
wherein the organic film is disposed directly on the two surfaces facing each other in the thickness direction of the insulating base material.

3. The laminate according to claim 2, further comprising:
a spacer disposed on a surface of the organic film in contact with the anisotropically conductive member.

4. The laminate according to claim 1, further comprising:
a winding core,
wherein the laminate is wound around the winding core in a state in which the anisotropically conductive member and the organic film are laminated.

5. The laminate according to claim 2, further comprising:
a winding core,
wherein the laminate is wound around the winding core in a state in which the anisotropically conductive member and the organic film are laminated.

6. The laminate according to claim 3, further comprising:
a winding core,
wherein the laminate is wound around the winding core in a state in which the anisotropically conductive member and the organic film are laminated.

7. The laminate according to claim 4,
wherein the winding core is composed of a cylinder, and flanges having a diameter larger than a diameter of the winding core are provided at both end parts of the winding core in an axial direction.

8. The laminate according to claim 1,
wherein the organic film is a porous film.

9. The laminate according to claim 2,
wherein the organic film is a porous film.

10. The laminate according to claim 3,
wherein the organic film is a porous film.

11. The laminate according to claim 1,
wherein a plurality of the anisotropically conductive members are arranged on at least one surface of the organic film in one direction.

12. The laminate according to claim 2,
wherein a plurality of the anisotropically conductive members are arranged on at least one surface of the organic film in one direction.

13. The laminate according to claim 3,
wherein a plurality of the anisotropically conductive members are arranged on at least one surface of the organic film in one direction.

14. The laminate according to claim 2,
wherein the anisotropically conductive member is disposed directly on each of the two surfaces facing each other in a thickness direction of the organic film.

15. A package comprising:
the laminate according to claim 1; and
a housing bag which houses the laminate.
wherein the housing bag has a gas permeability of oxygen of 1×10⁵ to 1 ml/(m²·day·MPa).

16. The package according to claim 15.
wherein. in the housing bag, a light transmittance is 1% or less in a wavelength range of 100 to 780 nm.
